(19) United States
(12) Patent Application Publication
(10) Pub. No.: US 2012/0015113 A1
(43) Pub. Date: Jan. 19, 2012

(54) METHODS FOR FORMING LOW STRESS DIELECTRIC FILMS

(75) Inventors: Zhong Qiang Hua, Saratoga, CA (US); Lei Luo, San Jose, CA (US); Manuel A. Hernandez, Santa Clara, CA (US); Shankar Venkataraman, Santa Clara, CA (US)

(73) Assignee: Applied Materials, Inc., Santa Clara, CA (US)

(21) Appl. No.: 12/835,574

(22) Filed: Jul. 13, 2010

(51) Int. Cl. C23C 16/513

(52) U.S. Cl. 427/579

(57) ABSTRACT

A method for forming a multi-layer silicon oxide film on a substrate includes performing a deposition cycle that comprises depositing a silicon oxide layer using a thermal chemical vapor deposition (CVD) process and depositing a silicon oxide layer using a plasma enhanced chemical vapor deposition (PECVD) process. The deposition cycle is repeated a specified number of times to form the multi-layer silicon oxide film comprising a plurality of silicon oxide layers formed using the thermal CVD process and a plurality of silicon oxide layers formed using the PECVD process. Each silicon oxide layer formed using the thermal CVD process is adjacent to at least one silicon oxide layer formed using the PECVD process.

### FIELD OF THE INVENTION

The present invention relates generally to methods for forming low stress dielectric films. Embodiments of the present invention may be used, for example, in applications involving semiconductor devices, semiconductor substrate processing, flat panel displays (such as TFTs), masks and filters, energy conversion and storage (such as photovoltaic cells, fuel cells, and batteries), solid-state lighting (such as LEDs and OLEDs), magnetic and optical storage, micro-electro-mechanical systems (MEMS) and nano-electro-mechanical systems (NEMS), micro-optic and optoelectronic devices, architectural and automotive glasses, and micro- and nano-molding.

### BACKGROUND

One of the primary steps in fabricating modern semiconductor devices is forming a dielectric layer on a semiconductor substrate. As is well known in the art, such a dielectric layer can be deposited by chemical vapor deposition (CVD). In a conventional thermal CVD process, reactive gases are supplied to the substrate surface where heat-induced chemical reactions take place to produce a desired film. In a conventional plasma enhanced CVD processes (PECVD), a plasma is formed to decompose and/or energize reactive species and promote reactions to produce a desired film. In general, reaction rates in thermal CVD and PECVD processes may be controlled using temperature, pressure, and/or reactant gas flow rates.

Increasingly stringent requirements for fabricating dielectric films, such as silicon oxides, are needed in order to produce high quality semiconductor devices. Many next-generation devices use vertical or 3D integration to increase device density. One challenge in vertical or 3D integration is forming thick silicon oxide layers that do not crack or peel. A layer that cracks or peels can cause defects that result in device failure. A film cracks or peels when a fracture energy of the film exceeds a cracking threshold. The fracture energy and cracking threshold depend in part on the thermal stress and thickness of the film. Thermal stress is measured at room temperature and results from differences in coefficients of thermal expansion between, for example, a film and an underlying substrate. Because the thermal stress for a particular film is generally constant for given deposition conditions, the cracking threshold is largely determined by deposition thickness. The deposition thickness at which the fracture energy is approximately equal to the cracking threshold can be called a critical thickness. Conventional silicon oxide deposition processes are unable to form silicon oxide films that exceed the critical thickness without cracking or peeling.

Thus, there is a need in the art for improved methods for forming thick silicon oxide films. These and other needs are addressed in the present application.

### SUMMARY

Embodiments of the present invention provide improved methods for forming silicon oxide films having low thermal stress that may be used, for example, in vertical or 3D integration. Such embodiments may be used to form thick silicon oxide layers that have low thermal stress and thus avoid cracking or peeling. The low thermal stress may be achieved by forming multi-layer silicon oxide films. As an example, a multi-layer silicon oxide film comprising thermal CVD layers and PECVD layers may be formed. The thermal CVD layers typically have a tensile thermal stress, while the PECVD layers typically have a compressive thermal stress. The thermal stress of the multi-layer silicon oxide film may be reduced compared to the absolute value of the thermal stress of the individual layers. Due to the reduced thermal stress, the thickness of the multi-layer silicon oxide film may be increased without exceeding the cracking threshold and causing cracking or peeling.

In accordance with an embodiment of the present invention, a method for forming a multi-layer silicon oxide film on a substrate includes depositing a first silicon oxide layer having a first thermal stress and a first thickness over the substrate using a thermal chemical vapor deposition (CVD) process. The first thermal stress and the first thickness provide a first fracture energy of the first silicon oxide layer that is less than a cracking threshold of the first silicon oxide layer. The method also includes depositing a second silicon oxide layer having a second thermal stress and a second thickness over the first silicon oxide layer using a plasma enhanced chemical vapor deposition (PECVD) process. The second thermal stress and the second thickness provide a second fracture energy of the second silicon oxide layer that is less than a cracking threshold of the second silicon oxide layer. The method also includes depositing a third silicon oxide layer having a third thermal stress and a third thickness over the second silicon oxide layer using the thermal CVD process. The third thermal stress and the third thickness provide a third fracture energy of the third silicon oxide layer that is less than a cracking threshold of the third silicon oxide layer. The method also includes depositing a fourth silicon oxide layer having a fourth thermal stress and a fourth thickness over the third silicon oxide layer using the PECVD process. The fourth thermal stress and the fourth thickness provide a fourth fracture energy of the fourth silicon oxide layer that is less than a cracking threshold of the fourth silicon oxide layer. The multi-layer silicon oxide film comprises the first silicon oxide layer, the second silicon oxide layer, the third silicon oxide layer, and the fourth silicon oxide layer, and a thermal stress and thickness of the multi-layer silicon oxide film provides a fracture energy of the multi-layer silicon oxide film that is less than a cracking threshold of the multi-layer silicon oxide film.

In accordance with another embodiment of the present invention, a method for forming a multi-layer silicon oxide film on a substrate includes performing a deposition cycle that comprises depositing a silicon oxide layer using a thermal chemical vapor deposition (CVD) process and depositing a silicon oxide layer using a plasma enhanced chemical vapor deposition (PECVD) process. The deposition cycle is repeated a specified number of times to form the multi-layer silicon oxide film comprising a plurality of silicon oxide layers formed using the thermal CVD process and a plurality of silicon oxide layers formed using the PECVD process. Each silicon oxide layer formed using the thermal CVD process is adjacent to at least one silicon oxide layer formed using the PECVD process.

Numerous benefits are achieved using the present invention over conventional techniques. For example, embodiments of the invention may be used to increase the thickness of a silicon oxide film without exceeding the cracking threshold and causing cracking or peeling. These and other benefits are described throughout the specification and more particularly below.

### BRIEF DESCRIPTION OF THE DRAWINGS

A further understanding of the nature and advantages of the invention may be realized by reference to the remaining portions of the specification and drawings. Like reference numerals are used throughout the several drawings to refer to similar components. In some instances, a sub-label is associated with a reference numeral and follows a hyphen to denote one of multiple similar components. When reference is made to a reference numeral without specification to an existing sub-label, it is intended to refer to all such multiple similar components.

FIGS. 1A-1B are cross-sectional views of a chemical vapor deposition apparatus that may be used in conjunction with embodiments of the invention;

FIG. 2 is a plot of thickness versus thermal stress for a thermal CVD silicon oxide film, a composite film including a thermal CVD silicon oxide layer and a PECVD silicon oxide layer, and a multi-layer silicon oxide film including a plurality of thermal CVD silicon oxide layers and a plurality of PECVD silicon oxide layers in accordance with an embodiment of the invention;

FIG. 3 is a simplified cross-sectional view of a multi-layer silicon oxide film on a semiconductor substrate in accordance with an embodiment of the invention;

FIG. 4 is a simplified flow chart illustrating an exemplary method of forming a multi-layer silicon oxide film in accordance with an embodiment of the invention; and

FIG. 5 is a simplified flow chart illustrating an exemplary method of forming a multi-layer silicon oxide film in accordance with another embodiment of the invention.

### DETAILED DESCRIPTION

The present invention provides methods for forming silicon oxide films having low thermal stress. As an example, an embodiment of the present invention provides a method of forming a multi-layer silicon oxide film. The multi-layer silicon oxide film may include layers formed using thermal CVD processes and layers formed using PECVD processes. The thermal stress of the thermal CVD silicon oxide layers is generally tensile, while thermal stress of the PECVD silicon oxide layers is generally compressive. The thermal stress of the individual thermal CVD and PECVD layers offset or counteract each other. This reduces an absolute value of the thermal stress of the multi-layer silicon oxide film compared to an absolute value of the thermal stress of the individual layers. The reduced stress increases the critical thickness of the multi-layer silicon oxide film. Thus, a thickness of the multi-layer silicon oxide film may be greater than a critical thickness of the individual layers of the film without causing cracking or peeling. Due to the reduced stress, the thickness can be increased before reaching the cracking threshold of the multi-layer silicon oxide film.

Silicon oxide layers formed using thermal CVD processes in accordance with embodiments of the present invention may use a variety of silicon precursors. Examples include silane (SiH₄), dichlorosilane (DCS), tetraethylorthosilicate (TEOS), octamethylcyclotetrasiloxane (OMCTS), and the like. The silicon precursor may be mixed with an oxygen source (e.g., O₂, ozone, etc.) and optionally a carrier gas (e.g., Ar, He, H₂, and/or N₂, etc.). The above compounds and elements are listed merely as examples and are not intended to be limiting. One of ordinary skill in the art would recognize many variations, modifications, and alternatives.

In an exemplary embodiment, the thermal CVD process is a sub-atmospheric CVD (SACVD) process using process gases that include TEOS, ozone, and N₂. In one embodiment the TEOS flow may be in the range of about 1.0 gm to about 4.0 gm, the ozone flow may be in the range of about 10000 sccm to about 20000 sccm, and the N₂ flow may be in the range of about 1000 sccm to about 5000 sccm. The temperature during the thermal CVD process may be in the range of about 200° C. to about 600° C., and the pressure may be in the range of about 200 Ton to about 760 Torr. Further details of exemplary thermal CVD processes that may be used in accordance with embodiments of the present invention are described in U.S. Pat. No. 5,963,840, entitled “Methods for Depositing Premetal Dielectric Layers at Sub-Atmospheric and High Temperature Conditions,” assigned to Applied Materials, Inc., the assignee of the present invention, the disclosure of which is hereby incorporated by reference in its entirety for all purposes.

Silicon oxide layers formed using PECVD processes in accordance with embodiments of the invention may use a variety of silicon precursors. Examples include tetraethylorthosilicate (TEOS) hexamethyldisilane (HMDS) tetramethyldisiloxane (TMDSO), and the like. The silicon precursor may be mixed with an oxygen source (e.g., O₂, ozone, etc.) and optionally a carrier gas (e.g., Ar, He, H₂, and/or N₂, etc.). The above compounds and elements are listed merely as examples and are not intended to be limiting. One of ordinary skill in the art would recognize many variations, modifications, and alternatives.

In an exemplary embodiment, the PECVD process may use process gases that include TEOS, O₂, ozone, and He. In one embodiment the TEOS flow may be in the range of about 0.5 gm to about 3.0 gm, the O₂ flow may be in the range of about 5000 sccm to about 10000 sccm, the ozone flow may be in the range of about 10000 sccm to about 20000 sccm, and the He flow may be in the range of about 5000 sccm to about 15000 sccm. The temperature during the PECVD process may be in the range of about 150° C. to about 600° C., and the pressure may be in the range of about 1 mTorr to about 20 Torr. The plasma may be formed either remotely or in situ using known plasma generation techniques.

### Exemplary Process Chamber

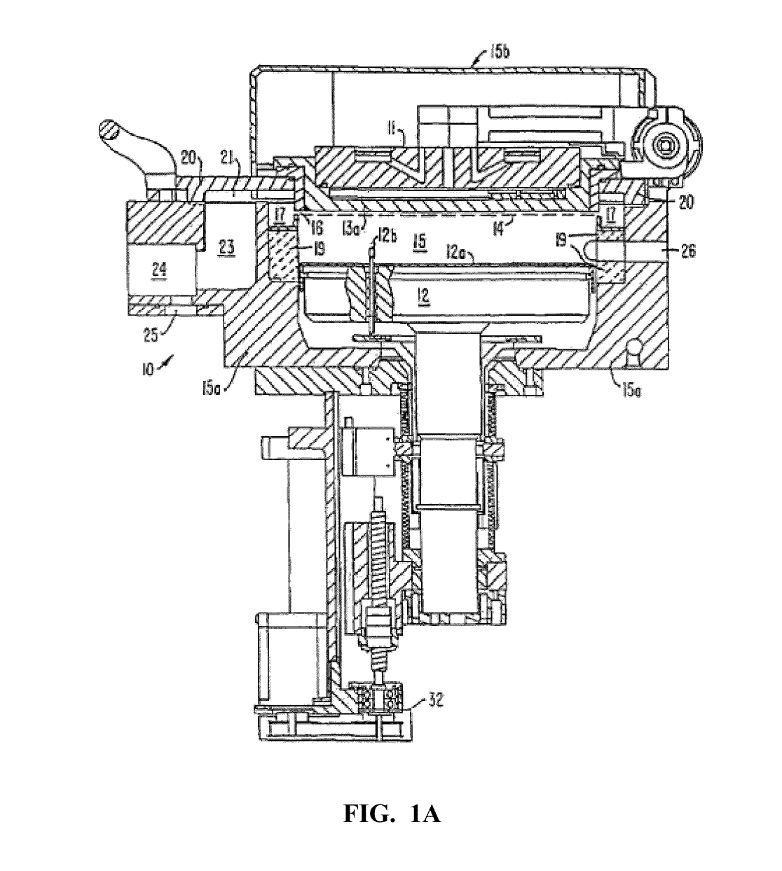

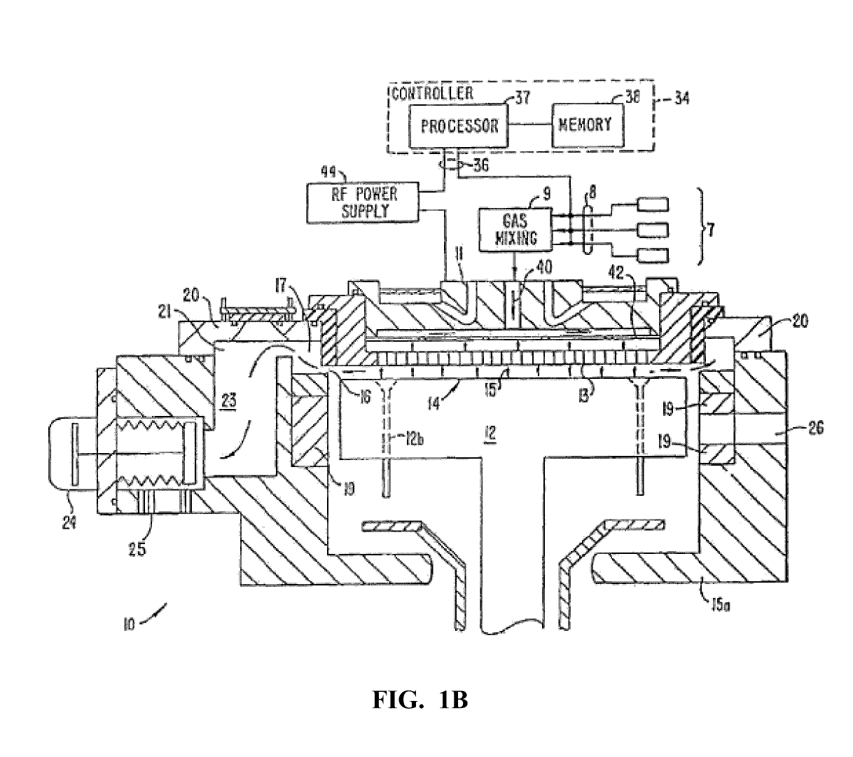

An exemplary CVD process chamber in which embodiments of the method of the present invention can be carried out is shown in FIGS. 1A and 1B. FIG. 1A shows a vertical, cross-sectional view of a CVD system 10 having a vacuum or processing chamber 15 that includes a chamber wall 15a and chamber lid assembly 15b.

CVD system 10 contains a gas distribution manifold 11 for dispersing process gases to a substrate (not shown) that rests on a heated pedestal or substrate support 12 centered within the process chamber. During processing, the substrate (e.g. a semiconductor wafer) may be positioned on a flat (or slightly convex) surface 12a of pedestal 12. The pedestal can be moved controllably between a lower loading/off-loading position (depicted in FIG. 1A) and an upper processing position (indicated by dashed line 14 in FIG. 1A and shown in FIG. 1B), which may be closely adjacent to manifold 11. A centerboard (not shown) may include sensors for providing information on the position of the wafers.

Deposition and carrier gases may be introduced into chamber 15 through perforated holes of a conventional flat, circular gas distribution member or faceplate. More specifically, deposition process gases may flow into the chamber through the inlet manifold 11 (indicated by arrow 40 in FIG. 1B), through a conventional perforated blocker plate 42, and then through holes in the gas distribution faceplate.

Before reaching the manifold, deposition and carrier gases may be input from gas sources 7 through gas supply lines 8 (FIG. 1B) into a mixing system 9, where they may be combined and then sent to manifold 11. Generally, the supply line for each process gas includes (i) several safety shut-off valves (not shown) that can be used to automatically or manually shut-off the flow of process gas into the chamber, and (ii) mass flow controllers (also not shown) that measure the flow of gas through the supply line. When toxic gases are used in the process, the several safety shut-off valves may be positioned on each gas supply line in conventional configurations.

The deposition process performed in CVD system 10 may be a plasma-enhanced process. In a plasma-enhanced process, an RF power supply 44 may apply electrical power between the gas distribution faceplate and the pedestal so as to excite the process gas mixture to form a plasma within the cylindrical region between the faceplate and the pedestal. This region will be referred to herein as the “reaction region”. Constituents of the plasma may react to deposit a desired film on the surface of the semiconductor wafer supported on pedestal 12. RF power supply 44 may be a mixed frequency RF power supply that typically supplies power at a high RF frequency (RF1) of about 13.56 MHz and at a low RF frequency (RF2) of about 350 KHz to enhance the decomposition of reactive species introduced into the vacuum chamber 15. In a thermal process, RF power supply 44 would not be utilized, and the process gas mixture thermally reacts to deposit the desired films on the surface of the semiconductor wafer supported on pedestal 12, which may be resistively heated to provide thermal energy for the reaction.

CVD system 10 may also be used for thermal deposition processes. During a thermal deposition process, a heat transfer liquid may be circulated through the walls 15a of the process chamber to maintain the chamber at a constant temperature to prevent condensation of liquid precursors and reduce gas phase reactions that could create particles. A portion of these heat-exchanging passages in the lid of chamber 15 are shown in FIG. 1B. The passages in the remainder of chamber walls 15a are not shown. Fluids used to heat the chamber walls 15a include the typical fluid types, i.e., water-based ethylene glycol or oil-based thermal transfer fluids. This heating (referred to as heating by the “heat exchanger”) may reduce or eliminate condensation of undesirable reactant products and improve the elimination of volatile by-products of the process gases and other contaminants that might contaminate the process if they were to condense on the walls of cool vacuum passages and migrate back into the processing chamber during periods of no gas flow.

The remainder of the gas mixture that is not deposited in a layer, including reaction byproducts, may be evacuated from the chamber by a vacuum pump (not shown). Specifically, the gases may be exhausted through an annular, slot-shaped orifice 16 surrounding the reaction region and into an annular exhaust plenum 17. The annular slot 16 and the plenum 17 may be defined by a gap between the top of the chamber's cylindrical side-wall 15a (including the upper dielectric lining 19 on the wall) and the bottom of the circular chamber lid 20. The 360° circular symmetry and uniformity of the slot orifice 16 and the plenum 17 help achieve a uniform flow of process gases over the wafer so as to deposit a uniform film on the wafer.

From the exhaust plenum 17, the gases flow underneath a lateral extension portion 21 of the exhaust plenum 17, past a viewing port (not shown), through a downward-extending gas passage 23, past a vacuum shut-off valve 24 (whose body may be integrated with the lower chamber wall 15a), and into the exhaust outlet 25 that connects to the external vacuum pump (not shown) through a foreline (also not shown).

The pedestal 12 (preferably aluminum, ceramic, or a combination thereof) may be resistively heated using an embedded single-loop heater element configured to make two full turns in the form of parallel concentric circles. An outer portion of the heater element may run adjacent to a perimeter of the support platter, while an inner portion may run on the path of a concentric circle having a smaller radius. The wiring to the heater element may pass through the stem of the pedestal 12. Typically, any or all of the chamber lining, gas inlet manifold faceplate, and various other reactor hardware are made out of material such as aluminum, anodized aluminum, or ceramic. An example of such a CVD apparatus is described in U.S. Pat. No. 5,558,717 entitled “CVD Processing Chamber,” issued to Zhao et al. and assigned to Applied Materials, Inc., the assignee of the present invention, and is hereby incorporated by reference in its entirety for all purposes.

A lift mechanism and motor 32 (FIG. 1A) raises and lowers the heater pedestal assembly 12 and its wafer lift pins 12b as wafers are transferred into and out of the body of the chamber by a robot blade (not shown) through an insertion/removal opening 26 in the side of the chamber 15. The motor 32 raises and lowers pedestal 12 between a processing position 14 and a wafer-loading position. The motor, valves or flow controllers connected to the supply lines 8, gas delivery system, throttle valve, RF power supply 44, chamber, substrate heating system, and heat exchangers H1, H2 are all controlled by a system controller 34 (FIG. 1B) over control lines 36 (of which only some are shown). Controller 34 relies on feedback from optical sensors to determine the position of movable mechanical assemblies such as the throttle valve and susceptor which are moved by appropriate motors under the control of controller 34.

In some embodiments, the system controller may include a hard disk drive (memory 38), a floppy disk drive, and a processor 37. The processor may contain a single-board computer (SBC), analog and digital input/output boards, interface boards, and/or stepper motor controller boards. Various parts of CVD system 10 conform to the Versa Modular European (VME) standard, which defines board, card cage, and connector dimensions and types. The VME standard also defines the bus structure as having a 16-bit data bus and a 24-bit address bus.

System controller 34 may control all of the activities of the CVD machine. The system controller executes system control software, which may be a computer program stored in a computer-readable medium such as a memory 38. Preferably, memory 38 is a hard disk drive, but it may also include other kinds of memory. The computer program may include sets of instructions that dictate the timing, mixture of gases, chamber pressure, chamber temperature, RF power levels, susceptor position, and other parameters of a particular process. Other computer programs stored on other memory devices including, for example, a floppy disk or other another appropriate drive, may also be used to operate controller 34.

### Experimental Results and Measurements

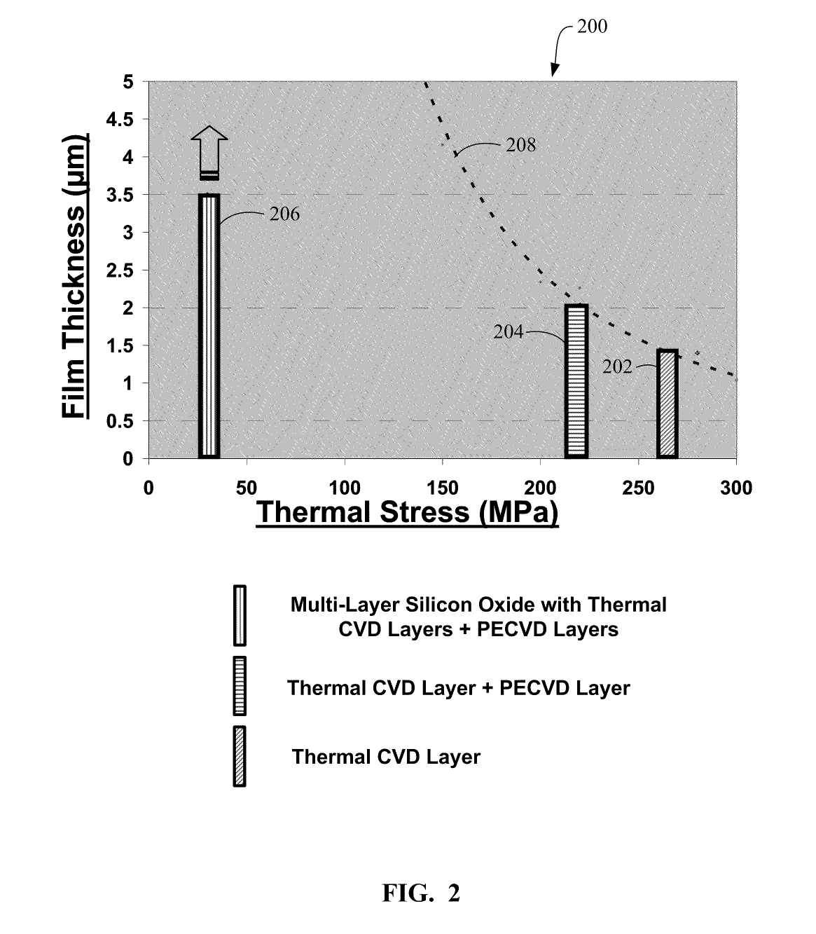

FIG. 2 is a plot 200 of thickness versus thermal stress for a thermal CVD silicon oxide film 202, a composite film 204 including a thermal CVD silicon oxide layer and a PECVD silicon oxide layer, and a multi-layer silicon oxide film 206 including a plurality of thermal CVD silicon oxide layers and a plurality of PECVD silicon oxide layers in accordance with an embodiment of the invention. In this example, the thermal CVD silicon oxide film 202 has a thickness of about 1.4 μm. The composite film 204 includes a thermal CVD silicon oxide layer having a thickness of about 1.7 μm, and a PECVD silicon oxide layer having a thickness of about 0.3 μm. The multi-layer silicon oxide film 206 has a plurality of thermal CVD layers that are each adjacent to at least one of a plurality of PECVD silicon oxide layers. In this example, the multi-layer silicon oxide film 206 has five thermal CVD silicon oxide layers. Each thermal CVD silicon oxide layer has a thickness of about 0.5 μm. The multi-layer silicon oxide film 206 also has five PECVD silicon oxide layers. Each PECVD silicon oxide layer has a thickness of about 0.3 μm.

In the plot 200, dashed line 208 indicating a critical thickness or a thickness at a cracking threshold for the thermal CVD silicon oxide film 202 and the composite film 204. As shown in the plot 200, the thermal CVD silicon oxide film 202 has a critical thickness of about 1.4 μm. At this thickness, the thermal CVD silicon oxide film 202 has a thermal stress of about +275 MPa. The composite film 204 has a critical thickness of about 2.0 μm. At this thickness, the composite film 204 has a thermal stress of about +200 MPa.

In contrast, the multi-layer silicon oxide film 206 has a critical thickness greater than about 3.5 μm as indicated by the arrow in plot 200. In this example, the thermal stress of the multi-layer silicon oxide film 206 is about +25 MPa. Due to the low thermal stress, the critical thickness of the multi-layer silicon oxide film is higher than that of the thermal CVD silicon oxide film 202 or the composite film 204 as indicated by the dashed line 208. In this example, the thickness and stress of the multi-layer silicon oxide film 206 provide a fracture energy that is below the cracking threshold. Thickness of the multi-layer silicon oxide film 206 is increased by reducing thickness of the thermal CVD silicon oxide layers and PECVD silicon oxide layers below their respective critical thickness or cracking threshold values. Thus, an absolute value of the thermal stress of the multi-layer silicon oxide film 206 is less than an absolute value of the thermal stress of the individual thermal CVD and PECVD layers.

Listed in TABLE 1 below are thickness are stress results for exemplary multi-layer silicon oxide films formed in accordance with embodiments of the present invention. The exemplary films are formed using a specified number of deposition cycles. Each deposition cycle comprises a thermal CVD process and a PECVD process. Thus, each deposition cycle forms a thermal CVD layer and an adjacent PECVD layer. For example, the film in the first row was formed using four deposition cycles. As shown in TABLE 1, multi-layer silicon oxide films having a thickness of between about 2.9 μm and 3.5 μm were formed having a thermal stress of between about −2 MPa to about +30 MPa. In comparison, the thermal stress of the thermal CVD silicon oxide film 202 in FIG. 2 is about +275 MPa at a thickness of about 1.4 μm, and the thermal stress of the composite film 204 having the thermal CVD layer with a thickness of about 1.4 μm and the PECVD layer with a thickness of about 0.6 μm is about +200 MPa.

TABLE 1

| | Target Thk. | Target Thk. | | Measured |
|---|---|---|---|---|
| | Thermal CVD | PECVD | Measured Thk. | Stress |
| Deposition | Layers | Layers | (Total Stack) | (Total Stack) |
| Cycles | (\acute{Å}) | (\acute{Å}) | (μm) | (MPa) |
| 4 | 5000 | 2600 | 2.9 | +27 |
| 4 | 5000 | 3700 | 3.2 | −2 |
| 4 | 6000 | 3700 | 3.5 | +30 |
| 5 | 5000 | 2600 | 3.5 | +25 |

While the thermal CVD and PECVD processes may be formed in different processing chambers, forming the layers in situ in the same processing chamber is preferred to avoid the thermal stress associated with temperature cycling. Also, while each thermal CVD layer is generally formed using the same process conditions as other thermal CVD layers, such a limitation is not required. Similarly, each PECVD layer does not have to be formed using the same process conditions as other PECVD layers. The thermal stress and thickness of each thermal CVD and/or PECVD process may be determined based on the desired thermal stress and thickness of the multi-layer silicon oxide film.

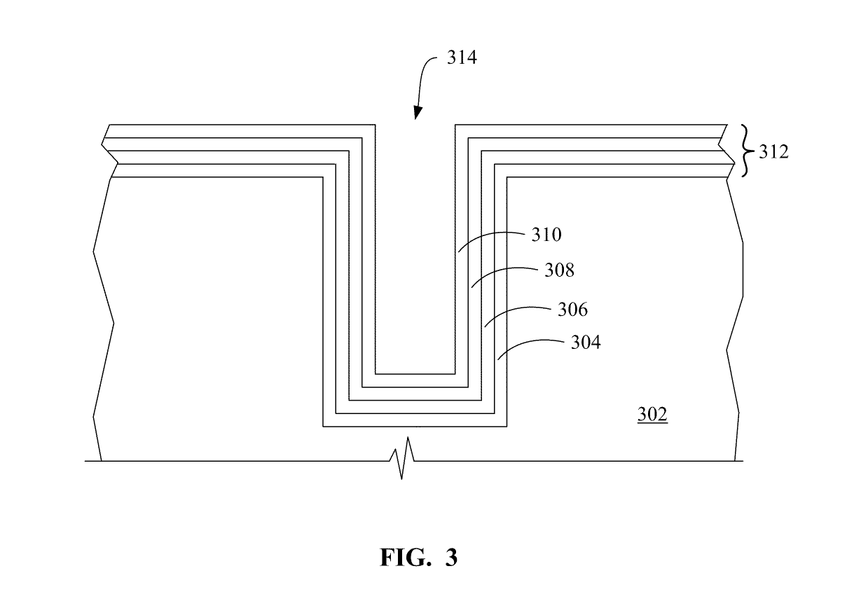

FIG. 3 is a simplified cross-sectional view of a multi-layer silicon oxide film 312 on a semiconductor substrate 302 in accordance with an embodiment of the invention. In this embodiment, the multi-layer silicon oxide film 312 is formed along a surface of the semiconductor substrate 302 and along sidewalls and bottom of trench 314. The multi-layer silicon oxide film 312 may be used as a liner to electrically isolate an interconnect or via that is subsequently formed in the trench 314. For example, the liner may be used to form a through-silicon via (TSV) in a 3D or vertical integration scheme. In this particular application, the trench 314 may have a width of between about 5 μm to about 50 μtm and a depth of up to about 100 μm, and the multi-layer silicon oxide film 312 may have a thickness of between about 2 μm to about 10 μm. As illustrated in the plot 200 of FIG. 2, the thermal CVD silicon oxide film 202 and the composite film 204 have a relatively low critical thickness and are thus not suited for such an application because of the cracking and peeling that occurs when the critical thickness is exceeded. As also illustrated in the plot 200, however, the multi-layer silicon oxide film 206 has a high critical thickness and thus is suitable for such applications without cracking or peeling.

As illustrated in FIG. 3, the multi-layer silicon oxide film 312 includes a first layer 304 formed using a thermal CVD process, a second layer 306 formed using a PECVD process, a third layer 308 formed using the thermal CVD process, and a fourth layer 310 formed using the PECVD process. Although the multi-layer silicon oxide film 312 shown in this example comprises layers 304, 306, 308, 310, multi-layer silicon oxide films formed in accordance with the present invention are not limited to any particular number of layers. Instead, each layer formed using a thermal CVD process and an adjacent layer formed using a PECVD process comprise a deposition cycle, and the multi-layer silicon oxide film may be formed using any number of deposition cycles depending on desired stress and thickness of the multi-layer silicon oxide film. Further, the multi-layer silicon oxide film may include a different number of layers formed using the thermal CVD process than the number of layers formed using the PECVD process.

### Exemplary Methods

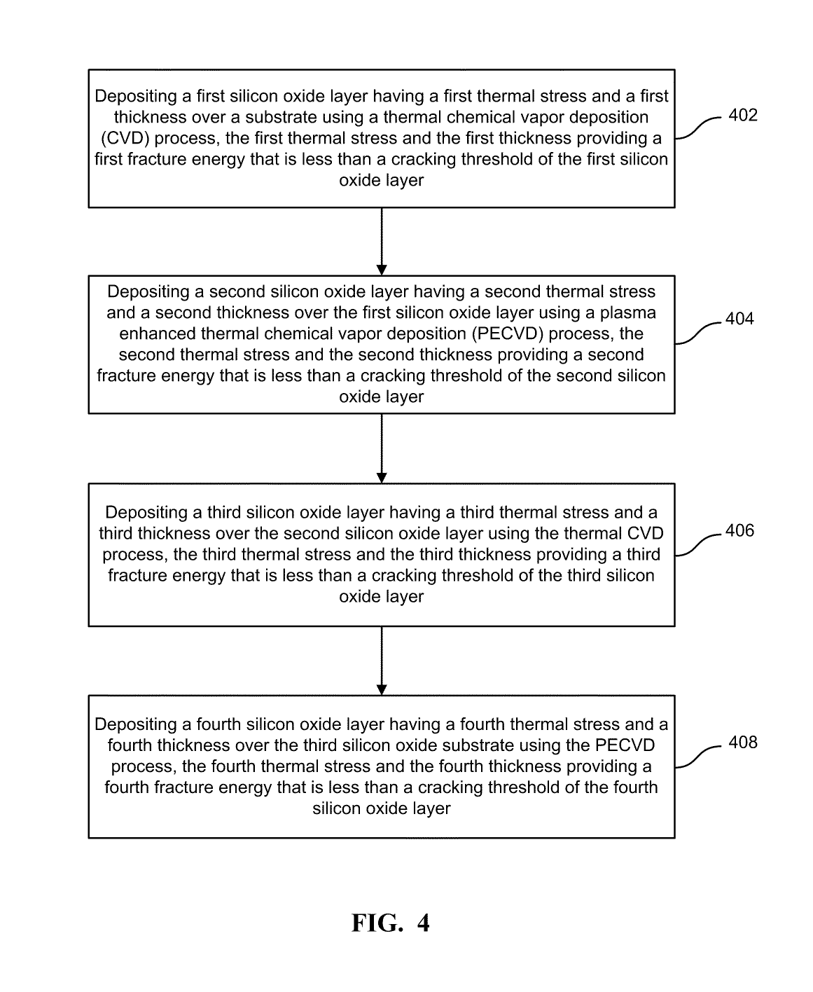

FIG. 4 is a simplified flow chart illustrating an exemplary method for forming a multi-layer silicon oxide film in accordance with an embodiment of the invention. A first silicon oxide layer having a first thermal stress and a first thickness is deposited over a substrate using a thermal CVD process (402). The first thermal stress and the first thickness provide a first fracture energy that is less than a cracking threshold of the first silicon oxide layer. A second silicon oxide layer having a second thermal stress and a second thickness is deposited over the first silicon oxide layer using a PECVD process (404). The second thermal stress and the second thickness provide a second fracture energy that is less than a cracking threshold of the second silicon oxide layer. A third silicon oxide layer having a third thermal stress and a third thickness is deposited over the second silicon oxide layer using the thermal CVD process (406). The third thermal stress and the third thickness provide a third fracture energy that is less than a cracking threshold of the third silicon oxide layer. A fourth silicon oxide layer having a fourth thermal stress and a fourth thickness is deposited over the third silicon oxide layer using the PECVD process (408). The fourth thermal stress and the fourth thickness provide a fourth fracture energy that is less than a cracking threshold of the fourth silicon oxide layer. The multi-layer silicon oxide film comprises the first silicon oxide layer, the second silicon oxide layer, the third silicon oxide layer, and the fourth silicon oxide layer. A thermal stress and thickness of the multi-layer silicon oxide film provides a fracture energy that is less than a cracking threshold of the multi-layer silicon oxide film.

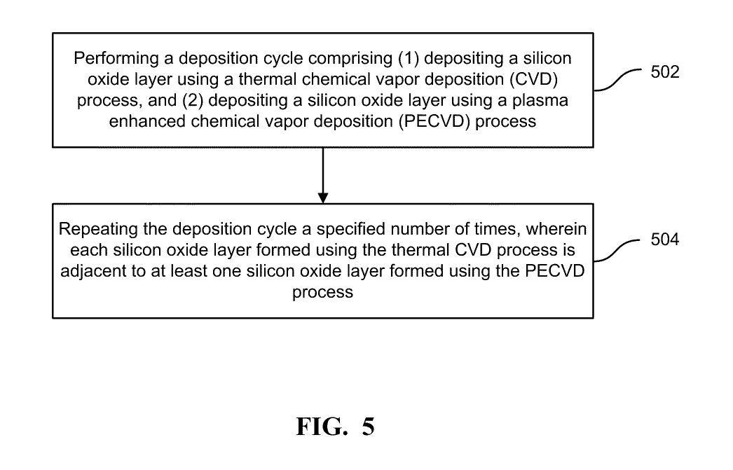

FIG. 5 is a simplified flow chart illustrating an exemplary method for forming a multi-layer silicon oxide film in accordance with another embodiment of the invention. A deposition cycle is performed that comprises depositing a silicon oxide layer using a thermal CVD process and depositing a silicon oxide layer using a PECVD process (502). The deposition cycle is repeated a specified number of times to form the multi-layer silicon oxide film comprising a plurality of silicon oxide layers formed using the thermal CVD process and a plurality of silicon oxide layers formed using the PECVD process. Each silicon oxide layer formed using the thermal CVD process may be adjacent to at least one of the silicon oxide layers formed using the PECVD process.

It should be appreciated that the specific steps illustrated in FIGS. 4-5 provide particular methods of forming a multi-layer silicon oxide film according to embodiments of the present invention. Other sequences of steps may also be performed according to alternative embodiments. For example, alternative embodiments of the present invention may perform the steps outlined above in a different order. Moreover, the individual steps illustrated in FIGS. 4-5 may include multiple sub-steps that may be performed in various sequences as appropriate to the individual step. Furthermore, additional steps may be added or removed depending on the particular application. One of ordinary skill in the art would recognize many variations, modifications, and alternatives.

While the present invention has been described in terms of specific embodiments, it should be apparent to those skilled in the art that the scope of the invention is not limited to the embodiments described herein. For example, it is to be understood that features of one or more embodiments of this invention may be combined with one or more features of other embodiments of the invention without departing from the scope of the invention. Also, examples and embodiments described herein are for illustrative purposes only, and various modifications or changes in light thereof will be evident to persons skilled in the art and are to be included within the spirit and purview of this application and scope of the appended claims.

What is claimed is:

1. A method for forming a multi-layer silicon oxide film on a substrate, the method comprising:
depositing a first silicon oxide layer having a first thermal stress and a first thickness over the substrate using a thermal chemical vapor deposition (CVD) process, the first thermal stress and the first thickness providing a first fracture energy of the first silicon oxide layer that is less than a cracking threshold of the first silicon oxide layer;
depositing a second silicon oxide layer having a second thermal stress and a second thickness over the first silicon oxide layer using a plasma enhanced chemical vapor deposition (PECVD) process, the second thermal stress and the second thickness providing a second fracture energy of the second silicon oxide layer that is less than a cracking threshold of the second silicon oxide layer;
depositing a third silicon oxide layer having a third thermal stress and a third thickness over the second silicon oxide layer using the thermal CVD process, the third thermal stress and the third thickness providing a third fracture energy of the third silicon oxide layer that is less than a cracking threshold of the third silicon oxide layer; and
depositing a fourth silicon oxide layer having a fourth thermal stress and a fourth thickness over the third silicon oxide layer using the PECVD process, the fourth thermal stress and the fourth thickness providing a fourth fracture energy of the fourth silicon oxide layer that is less than a cracking threshold of the fourth silicon oxide layer, wherein the multi-layer silicon oxide film comprises the first silicon oxide layer, the second silicon oxide layer, the third silicon oxide layer, and the fourth silicon oxide layer, and a thermal stress and thickness of the multi-layer silicon oxide film provides a fracture energy of the multi-layer silicon oxide film that is less than a cracking threshold of the multi-layer silicon oxide film.

2. The method of claim 1 wherein a deposition cycle comprises depositing a silicon oxide layer using the thermal CVD process and depositing a silicon oxide layer using the PECVD process, and the method further comprises repeating the deposition cycle a specified number of times to form the multi-layer silicon oxide film.

3. The method of claim 1 wherein the first thermal stress of the first silicon oxide layer is opposite in force from the second thermal stress of the second silicon oxide layer.

4. The method of claim 1 wherein the first thermal stress and the third thermal stress are tensile, and the second thermal stress and the fourth thermal stress are compressive.

5. The method of claim 1 wherein an absolute value of the thermal stress of the multi-layer silicon oxide film is less than an absolute value of the first thermal stress of the first silicon oxide layer.

6. The method of claim 1 wherein an absolute value of the thermal stress of the multi-layer silicon oxide film is less than an absolute value of the second thermal stress of the second silicon oxide layer.

7. The method of claim 1 wherein the multi-layer silicon oxide film is formed in situ in a processing chamber.

8. The method of claim 1 wherein the thickness of the multi-layer silicon oxide film is at least about 3.5 μm.

9. The method of claim 1 wherein the first thickness of the first silicon oxide layer is about 1.4 μm or less.

10. The method of claim 1 wherein the second thickness of the second silicon oxide layer is about 0.6 μm or less.

11. A method for forming a multi-layer silicon oxide film on a substrate, the method comprising:
performing a deposition cycle comprising:
depositing a silicon oxide layer using a thermal chemical vapor deposition (CVD) process;
depositing a silicon oxide layer using a plasma enhanced chemical vapor deposition (PECVD) process;
repeating the deposition cycle a specified number of times to form the multi-layer silicon oxide film comprising a plurality of silicon oxide layers formed using the thermal CVD process and a plurality of silicon oxide layers formed using the PECVD process, wherein each silicon oxide layer formed using the thermal CVD process is adjacent to at least one silicon oxide layer formed using the PECVD process.

12. The method of claim 11 wherein a thermal stress of the silicon oxide layer formed using the thermal CVD process is opposite in force from a thermal stress of the silicon oxide layer formed using the PECVD process.

13. The method of claim 11 wherein a thermal stress of the silicon oxide layer formed using the thermal CVD process is tensile, and a thermal stress of the silicon oxide layer formed using the PECVD process is compressive.

14. The method of claim 11 wherein an absolute value of a thermal stress of the multi-layer silicon oxide film is less than an absolute value of a thermal stress of the silicon oxide layer formed using the thermal CVD process.

15. The method of claim 11 wherein an absolute value of a thermal stress of the multi-layer silicon oxide film is less than an absolute value of a thermal stress of the silicon oxide layer formed using the PECVD process.

16. The method of claim 11 wherein the multi-layer silicon oxide film has a thickness greater than about 3 μm.
